(19) United States
(12) Patent Application Publication
(10) Pub. No.: US 2026/0270333 A1
(43) Pub. Date: Sep. 10, 2026

(54) COVER PLATE SEPARATION MEMBER AND ELECTRONIC DEVICE INCLUDING SAME

(71) Applicant: Samsung Electronics Co., Ltd., Suwon-si, Gyeonggi-do (KR)

(72) Inventors: Kyonghwan CHO, Suwon-si (KR); Byeongjin JUNG, Suwon-si (KR); Jongmin KIM, Suwon-si (KR); Hyoseok NA, Suwon-si (KR); Sangho HONG, Suwon-si (KR); Jaehyun KWON, Suwon-si (KR); Seongeun BAE, Suwon-si (KR); Soojung LEE, Suwon-si (KR)

(21) Appl. No.: 19/669,297

(22) Filed: May 6, 2026

Related U.S. Application Data
(63) Continuation of application No. PCT/KR2024/017484, filed on Nov. 7, 2024.

(30) Foreign Application Priority Data
Nov. 7, 2023 (KR) 10-2023-0152782
Jan. 9, 2024 (KR) 10-2024-0003761

(51) Int. Cl. H04M 1/02

(52) U.S. Cl. CPC H04M 1/0249; H04M 1/0203; H04M 1/026

(57) ABSTRACT

A cover plate separation member separation member for an electronic device including a frame, a cover plate, and an adhesive member for bonding the frame and the cover plate is provided. The cover plate separation member includes a high thermal conductivity area which is a relatively high thermal conductivity and positioned to at least partially overlap the adhesive member when the cover plate separation member is positioned on the cover plate, and a low thermal conductivity area which has a relatively low thermal conductivity compared to the high thermal conductivity area and positioned to at least partially overlap an area of the electronic device where the adhesive member is not positioned when the cover plate separation member is positioned on the cover plate.

### CROSS-REFERENCE TO RELATED APPLICATION(S)

This application is a continuation application, claiming priority under 35 U.S.C. § 365 (c), of an International application No. PCT/KR2024/017484, filed on Nov. 7, 2024, which is based on and claims the benefit of a Korean patent application number 10-2023-0152782, filed on Nov. 7, 2023, in the Ministry of Intellectual Property (MOIP), and of a Korean patent application number 10-2024-0003761, filed on Jan. 9, 2024, in the Ministry of Intellectual Property (MOIP), the disclosure of each of which is incorporated by reference herein in its entirety.

### BACKGROUND

### 1. Field

The disclosure relates to an electronic device and a repair device thereof. More particularly, the disclosure relates to a cover plate separation member and an electronic device including same.

### 2. Description of Related Art

Electronic devices may include various elements such as a battery, a display panel, and a storage. Various elements of an electronic device may experience performance degradation, may experience malfunction, or may cease to operate due to aging and/or external factors (e.g., impact, heat generation, over-current, immersion, and/or a magnetic field) applied during use, and thus may require repair.

Recently, there has been an increasing demand for repair accessibility and ease of repair of electronic devices for the consumer's right to repair and for resource conservation and environmental protection. As a result, there is also an increasing demand for repair materials (e.g., repair kits) that facilitate the repair of faults in electronic devices owned by consumers.

An electronic device includes a housing for protecting inner elements. The housing may include a frame and a cover plate (e.g., a front plate and a rear plate) fixed to the frame. The housing may be waterproofed to provide waterproofness to the electronic device. For example, the cover plate of the electronic device may be sealed with respect to the frame by a means such as an adhesive. The housing described above should be opened when the electronic device is repaired.

The above information is presented as background information only to assist with an understanding of the disclosure. No determination has been made, and no assertion is made, as to whether any of the above might be applicable as prior art with regard to the disclosure.

### SUMMARY

When an electronic device is repaired, heat may be applied to an adhesive means for attaching a cover plate to a frame so as to weaken the adhesive forth and then separate the cover plate. When heat is applied to the cover plate of the electronic device, an element such as a battery or a display of the electronic device may be damaged by the heat. In addition, for example, when a pick is inserted between the cover plate and the frame in order to separate the cover plate, there may be a risk that an element (e.g., an antenna structure and/or a cable) of the electronic device, which is positioned between the cover plate and the frame, is damaged.

Aspects of the disclosure are to address at least the above-mentioned problems and/or disadvantages and to provide at least the advantages described below. Accordingly, an aspect of the disclosure is to provide a cover plate separation member configured to reduce the risk of thermal damage to elements of an electronic device when a cover plate is separated.

Another aspect of the disclosure is to provide a cover plate separation member configured to reduce the risk of damage to elements of an electronic device when a cover plate is separated.

Additional aspects will be set forth in part in the description which follows and, in part, will be apparent from the description, or may be learned by practice of the presented embodiments.

In accordance with an aspect of the disclosure, a cover plate separation member separation member for an electronic device including a frame, a cover plate, and an adhesive member configured to bond the frame and the cover plate is provided. The cover plate separation member includes a high thermal conductivity area which has a relatively high thermal conductivity and is positioned to at least partially overlap the adhesive member when the cover plate separation member is positioned on the cover plate, and a low thermal conductivity area having a relatively low thermal conductivity compared to the high thermal conductivity area and positioned to at least partially overlap an area of the electronic device, in which the adhesive member is not positioned when the cover plate separation member is positioned on the cover plate.

In various embodiments, the cover plate separation member includes a protective cover positioned in a first direction which is opposite to a direction facing the cover plate when the cover plate separation member is positioned on the cover plate.

In various embodiments, the electronic device includes at least one inner element positioned between the frame and the cover plate, and the protective cover includes a caution display area formed on a surface facing the first direction and positioned to overlap the at least one of inner elements.

In various embodiments, the low thermal conductivity area includes an air layer formed between the cover plate and the protective cover when the cover plate separation member is positioned on the cover plate.

In various embodiments, the cover plate separation member includes a support member which is positioned between the cover plate and the protective cover when the cover plate separation member is positioned on the cover plate and supports the protective cover so that the protective cover and the cover plate are spaced apart from each other.

In various embodiments, the high thermal conductivity area extends to cover a side surface of the protective cover and at least a portion of a surface, which faces the first direction, of the protective cover.

In various embodiments, the high thermal conductivity area includes a metal foil.

In various embodiments, the electronic device includes a curved-surface portion formed in at least a portion of an edge of the cover plate, and the metal foil has a portion which corresponds to the curved-surface portion and is bent to correspond to a curvature of the curved-surface portion when the cover plate separation member is positioned on the cover plate.

In various embodiments, the electronic device includes at least one protruding portion formed on the cover plate, and the cover plate separation member includes a cut-out portion which has a position and a shape corresponding to the protruding portion and is formed such that at least a portion of the protruding portion is positioned therein when the cover plate separation member is positioned on the cover plate.

In accordance with another aspect of the disclosure, a cover plate is provided. The cover plate includes a frame, a cover plate positioned in a first direction with respect to the frame, separation member an adhesive member positioned on at least a partial area between the frame and the cover plate and configured to bond the frame and the cover plate, and a cover plate separation member configured to be attachable in the first direction with respect to the cover plate, wherein the cover plate separation member includes a high thermal conductivity area which has a relatively high thermal conductivity and is positioned to at least partially overlap the adhesive member when the cover plate separation member is positioned on the cover plate, and a low thermal conductivity area which has a relatively low thermal conductivity compared to the high thermal conductivity area and positioned to at least partially overlap an area of the electronic device, in which the adhesive member is not positioned when the cover plate separation member is positioned on the cover plate.

In various embodiments, the cover plate separation member includes a protective cover positioned in a first direction which is opposite to a direction facing the cover plate when positioned on the cover plate.

In various embodiments, the low thermal conductivity area includes an air layer formed between the cover plate and the protective cover when the cover plate separation member is positioned on the cover plate.

In various embodiments, the high thermal conductivity area extends to cover a side surface of the protective cover and at least a portion of a surface, which faces the first direction, of the protective cover.

In various embodiments, the high thermal conductivity area includes a metal foil.

In various embodiments, the cover plate includes a curved-surface portion formed in at least a portion of an edge thereof, and the metal foil has a portion which corresponds to the curved-surface portion and is bent to correspond to a curvature of the curved-surface portion when the cover plate separation member is positioned on the cover plate.

In accordance with another aspect of the disclosure, a method for separating a cover plate of an electronic device is provided. Wherein the electronic device includes a frame, a cover plate positioned in a first direction with respect to the frame, an adhesive member positioned in at least a partial area between the frame and the cover plate and configured to bond the frame and the cover plate, separation member separation member separation member separation member wherein the method for separating a cover plate includes an attachment operation of attaching a cover plate separation member to the cover plate in a first direction, a heating operation of contacting a heat source to the cover plate separation member in the first direction, an adhesion release operation of inserting a wedge between the frame and the cover plate to remove adhesion of the adhesive member, and a separation operation of separating the cover plate from the frame, and wherein the cover plate separation member includes a high thermal conductivity area which has a relatively high thermal conductivity and is positioned to at least partially overlap the adhesive member when the cover plate separation member is positioned on the cover plate, and a low thermal conductivity area which has a relatively low thermal conductivity compared to the high thermal conductivity area and is positioned to at least partially overlap an area of the electronic device, in which the adhesive member is not positioned when the cover plate separation member is attached on the cover plate.

In various embodiments, the cover plate separation member includes a protective cover positioned in a first direction which is opposite to a direction facing the cover plate when positioned on the cover plate.

In various embodiments, the electronic device includes at least one inner element positioned between the frame and the cover plate, and the protective cover includes a caution display area formed on a surface facing the first direction and positioned to overlap the at least one of inner element.

In various embodiments, the high thermal conductivity area includes a metal foil.

In various embodiments, the electronic device includes at least one protruding portion formed on the cover plate, and the cover plate separation member includes a cut-out portion which has a position and a shape corresponding to the protruding portion and is formed such that at least a portion of the protruding portion is positioned therein when the cover plate separation member is positioned on the cover plate.

According to various embodiments of the disclosure, the heat transfer amount for an area in which an adhesive member is disposed on a cover plate is improved by a high thermal conductivity area, the heat transfer amount for inner elements of an electronic device is reduced by a low thermal conductivity area, and thus an electronic device in which thermal damage to inner elements is reduced is provided. In addition, a caution display area is formed on a first surface of a protective cover, and thus a cover plate separation member capable of reducing the risk of damage to inner elements of an electronic device is provided when a cover plate is separated by a user.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2A is a front perspective view of an electronic device according to an embodiment of the disclosure;

FIG. 2B is a rear perspective view of an electronic device according to an embodiment of the disclosure;

FIG. 3 is a deployed perspective view of an electronic device according to an embodiment of the disclosure;

FIG. 4A is an exploded perspective view of an electronic device according to an embodiment of the disclosure;

FIG. 4B is a plan view showing an inner configuration of an electronic device according to an embodiment of the disclosure;

FIG. 4C is a plan view showing a cover plate separation member according to an embodiment of the disclosure;

FIG. 4D is a cross-sectional schematic view showing a cover plate separation member according to an embodiment of the disclosure;

FIG. 4E is a cross-sectional schematic view showing an operation of a cover plate separation member according to an embodiment of the disclosure;

FIG. 4F is a cross-sectional schematic view showing a cover plate separation member according to an embodiment of the disclosure;

FIG. 5A is a plan view of a cover plate separation member according to an embodiment of the disclosure;

FIG. 5B is a cross-sectional view schematically showing an electronic device according to an embodiment of the disclosure;

FIG. 6A is a plan view of a cover plate separation member according to an embodiment of the disclosure;

FIG. 6B is a cross-sectional view schematically showing an electronic device according to an embodiment of the disclosure;

FIG. 6C is a schematic view showing a separation operation of a cover plate of an electronic device according to an embodiment of the disclosure;

FIG. 7A is a cross-sectional view schematically showing an electronic device according to an embodiment of the disclosure;

FIG. 7B is a plan view of a cover plate separation member according to an embodiment of the disclosure;

FIG. 8 is a cross-sectional view showing an electronic device according to an embodiment of the disclosure;

FIG. 9 is a cross-sectional view showing an electronic device according to an embodiment of the disclosure;

FIG. 10 is a flowchart showing a method for separating a cover plate of an electronic device according to an embodiment of the disclosure; and

FIGS. 11A, 11B, 11C, and 11D are schematic views showing operations of removing a cover plate of an electronic device according to various embodiments of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

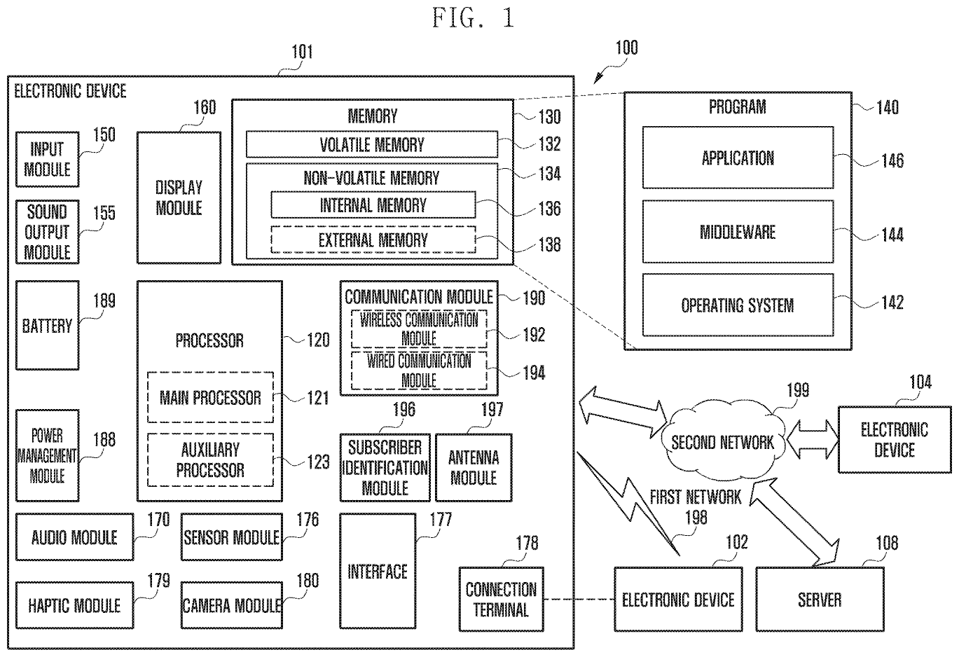

FIG. 1 is a block diagram illustrating an electronic device in a network environment according to an embodiment of the disclosure.

Referring to FIG. 1, an electronic device 101 in a network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell. The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or user plane (U-plane) latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197. According to various embodiments, the antenna module 197 may form a mm Wave antenna module. According to an embodiment, the mm Wave antenna module may include a printed circuit board, a RFIC disposed on a first surface (e.g., the bottom surface) of the printed circuit board, or adjacent to the first surface and capable of supporting a designated high-frequency band (e.g., the mm Wave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or the server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments disclosed in this document may be implemented in various forms. For example, the electronic device may include a portable communication device (e.g., a smartphone), a computer device, a portable multimedia device, a portable medical device, a camera, a wearable device, or a home appliance. The electronic device according to the embodiments of this document is not limited to the above-described devices.

It should be appreciated that the embodiments and the terms used therein are not intended to limit the technological features set forth herein to particular embodiments and the disclosure includes various changes, equivalents, or alternatives for a corresponding embodiment. As used herein, each of such phrases as “A or B,” “at least one of A and B,” “at least one of A or B,” “A, B, or C,” “at least one of A, B, and C,” and “at least one of A, B, or C,” may include any one or all possible combinations of the items enumerated together in a corresponding one of the phrases. Such terms as “a first,” “a second,” “the first,” and “the second” may be used to simply distinguish a corresponding element from another, and does not limit the elements in other aspect (e.g., importance or order). If an element (e.g., a first element) is referred to, with or without the term “operatively” or “communicatively”, as “coupled with/to” or “connected with/to” another element (e.g., a second element), it means that the element may be coupled/connected with/to the other element directly (e.g., wiredly), wirelessly, or via a third element.

As used in various embodiments of the disclosure, the term “module” may include a unit implemented in hardware, software, or firmware, and may be interchangeably used with other terms, for example, “logic,” “logic block,” “component,” or “circuit”. The “module” may be a single integrated component, or a minimum unit or part thereof, adapted to perform one or more functions. For example, according to an embodiment, the “module” may be implemented in the form of an application-specific integrated circuit (ASIC).

Various embodiments as set forth herein may be implemented as software (e.g., the program 140) including one or more instructions that are stored in a storage medium (e.g., the internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it. This allows the machine to be operated to perform at least one function according to the at least one instruction invoked. The one or more instructions may include codes generated by a compiler or code executable by an interpreter. The machine-readable storage medium may be provided in the form of a non-transitory storage medium. Herein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, methods according to various embodiments of the disclosure may be included and provided in a computer program product. The computer program product may be traded as a product between a seller and a purchaser. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each element (e.g., a module or a program) of the above-described elements may include a single entity or multiple entities, and some of the multiple entities may be separately disposed in another element. According to various embodiments, one or more of the above-described elements or operations may be omitted, or one or more other elements or operations may be added. Alternatively or additionally, a plurality of elements (e.g., modules or programs) may be integrated into a single element. In such a case, according to various embodiments, the integrated element may still perform one or more functions of each of the plurality of elements in the same or similar manner as they are performed by a corresponding one of the plurality of elements before the integration. According to various embodiments, operations performed by the module, the program, or another element may be carried out sequentially, in parallel, repeatedly, or heuristically, or one or more of the operations may be executed in a different order or omitted, or one or more other operations may be added.

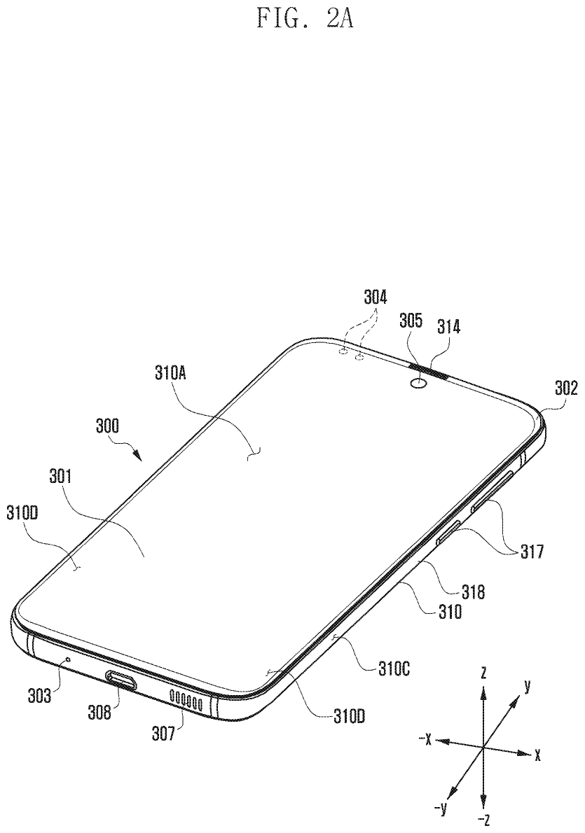

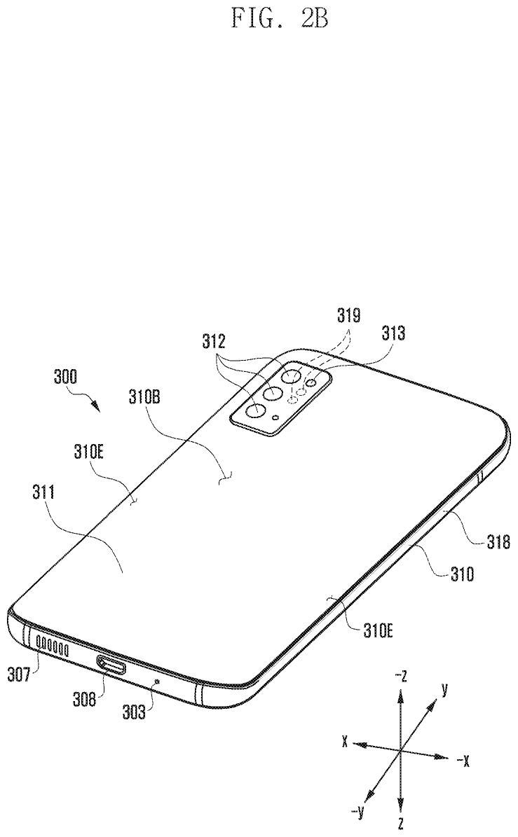

FIG. 2A is a front perspective view of an electronic device according to an embodiment of the disclosure.

FIG. 2B is a rear perspective view of an electronic device according to an embodiment of the disclosure.

An electronic device 300 of FIGS. 2A and 2B according to various embodiments may be at least partially similar to the electronic device 101 of FIG. 1 or may include other embodiments of an electronic device.

Referring to FIGS. 2A and 2B, the electronic device 300 according to an embodiment may include a housing 310 including a first surface (or a front surface) 310A, a second surface (or a rear surface) 310B, and a side surface 310C surrounding a space between the first surface 310A and the second surface 310B. In another embodiment (not shown), the housing 310 may refer to a structure which forms a portion of the first surface 310A, the second surface 310B, and the side surface 310C of FIGS. 2A and 2B. According to an embodiment, at least a portion of the first surface 310A may be formed by a front plate 302 (e.g., a glass plate or a polymer plate including various coating layers) which is substantially transparent. The second surface 310B may be formed by a substantially opaque rear plate 311. For example, the rear plate 311 may be formed by coating or colored glass, ceramic, polymer, metal (e.g., aluminum, stainless steel (STS), or magnesium), or a combination of at least two of the above materials. The side surface 310C may be formed by a side bezel structure (or “side member”) 318 which is coupled to the front plate 302 and the rear plate 311 and includes a metal and/or a polymer. In some embodiments, the rear plate 311 and the side bezel structure 318 may be integrally formed and may include the same material (e.g., a metal material such as aluminum).

In the illustrated embodiment, the front plate 302 may include, at opposite ends of the long edge of the front plate 302, first areas 310D which are bent from the first surface 310A toward the rear plate 311 and extend seamlessly. In the illustrated embodiment (e.g., see FIG. 2B), the rear plate 311 may include, at opposite ends of the long edge, second areas 310E which are bent from the second surface 310B toward the front plate 302 and extend seamlessly. In some embodiments, the front plate 302 or the rear plate 311 may include only one of the first areas 310D or the second areas 310E. In some embodiments, the front plate 302 may not include the first areas 310D and the second areas 310E, and may include only a flat plane disposed in parallel with the second surface 310B. In the above embodiments, when viewed from the side surface of the electronic device 300, the side bezel structure 318 may have a first thickness (or width) at the side surface where the first areas 310D or the second areas 310E are not included, and may have a second thickness which is thinner than the first thickness at the side surface where the first areas or the second areas are included.

According to an embodiment, the electronic device 300 may include at least one of a display 301 (e.g., the display module 160 of FIG. 1), an input device 303 (e.g., the input module 150 of FIG. 1), sound output devices 307 and 314 (e.g., the sound output module 155 of FIG. 1), sensor modules 304 and 319 (e.g., the sensor module 176 of FIG. 1), camera modules 305, 312, and 313 (e.g., the camera module 180 of FIG. 1), key input devices 317, an indicator (not shown) (e.g., the interface 177 of FIG. 1), and a connector 308 (e.g., the connection terminal 178 of FIG. 1). In some embodiments, at least one of elements (e.g., the key input devices 317 or the indicator) may be omitted from the electronic device 300, and other elements may be additionally included therein.

The display 301, for example, may be exposed through a substantial portion of the front plate 302. In some embodiments, at least a portion of the display 301 may be exposed through the front plate 302 forming the first surface 310A and the first areas 310D of the side surface 310C. The display 301 may be coupled to or disposed adjacent to a touch detection circuit, a pressure sensor capable of measuring the intensity (pressure) of a touch, and/or a digitizer for detecting a magnetic-field-type stylus pen. In some embodiments, at least a portion of the sensor modules 304 and 319 and/or at least a portion of the key input devices 317 may be disposed in the first area 310D and/or the second area 310E.

The input device 303 may include a microphone 303. In some embodiments, the input device 303 may include a plurality of microphones 303 disposed to detect the direction of sound. The sound output devices 307 and 314 may include speakers 307 and 314. The speakers 307 and 314 may include an external speaker 307 and a microphone 303 for calling. In some embodiments, the microphone 303, the speakers 307 and 314, and the connector 308 may be disposed in a space of the electronic device 300 and may be exposed to the external environment through at least one hole formed in the housing 310. In some embodiments, a hole formed in the housing 310 may be used in common for the microphone 303 and the speakers 307 and 314. In some embodiments, the sound output device 307 or 314 may include a speaker (e.g., a piezoelectric speaker) which operates without a hole formed in the housing 310.

The sensor module 304 or 319 may generate an electrical signal or a data value corresponding to an operating state of the inside of the electronic device 300 or an external environmental state. For example, the sensor modules 304 and 319 may include a first sensor module 304 (e.g., a proximity sensor) and/or a second sensor module (not shown) (e.g., a fingerprint sensor) disposed on the first surface 310A of the housing 310, and/or a third sensor module 319 (e.g., a heart rate monitor (HRM) sensor) disposed on the second surface 310B of the housing 310. The fingerprint sensor may be disposed on the first surface 310A of the housing 310. The fingerprint sensor (e.g., an ultrasonic or optical fingerprint sensor) may be disposed on the first surface 310A under the display 301. The electronic device 300 may further include at least one of sensor module not shown, for example, a gesture sensor, a gyro sensor, a pressure sensor, a magnetic sensor, an acceleration sensor, a grip sensor, a color sensor, an infrared (IR) sensor, a biometric sensor, a temperature sensor, a humidity sensor, or a light sensor 304.

The camera modules 305, 312, and 313 may include a first camera device 305 disposed on the first surface 310A of the electronic device 300, and a second camera device 312 and/or a flash 313 disposed on the second surface 310B. The camera module 305 or 312 may include one or more lenses, an image sensor, and/or an image signal processor. For example, the flash 313 may include a light-emitting diode or a xenon lamp. In some embodiments, two or more lenses (e.g., a wide-angle lens and a telephoto lens) and image sensors may be disposed on one surface of the electronic device 300.

The key input device 317 may be disposed on the side surface 310C of the housing 310. In another embodiment, the electronic device 300 may not include a portion or all of the above-mentioned key input devices 317, and a key input device 317 not included may be implemented in another form, such as a soft key, on the display 301. In another embodiment, the key input device 317 may be implemented using a pressure sensor included in the display 301.

For example, the indicator (not shown) may be disposed on the first surface 310A of the housing 310. For example, the indicator may provide state information of the electronic device 300 in the form of light. In another embodiment, for example, the light-emitting element may provide a light source which operates in conjunction with an operation of the camera module 305. For example, the indicator may include a light emitting diode (LED), an IR LED, and a xenon lamp.

The connector hole 308 may include a connector hole for accommodating a connector (e.g., a USB connector or an interface connector port module) for transmitting and receiving power and/or data to and from an external electronic device, and/or a connector hole (or an earphone jack) for accommodating a connector for transmitting and receiving audio signals to and from an external electronic device.

A camera module 305 of the camera modules 305 and 312, a sensor module 304 of the sensor modules 304 and 319, or the indicator may be disposed to be exposed through the display 301. For example, the camera module 305, the sensor module 304, or the indicator may be disposed in an inner space of the electronic device 300 so as to come into contact with an external environment through an opening perforated to the front plate 302 of the display 301 or a transmissive area. According to an embodiment, the area in which the display 301 and the camera module 305 face each other may be formed as a transmissive area having a predetermined transmittance as a portion of an area for displaying contents. According to an embodiment, the transmissive area may be formed to have a transmittance of about 5% to 20%. The transmissive area may include an area which overlaps an effective area (e.g., a field-of-view area), through which light for forming an image on an image sensor to generate an image passes, of the camera module 305. For example, the transmissive area of the display 301 may include an area of which the density of pixels is lower than the surrounding areas. For example, the transmissive area may replace the opening. For example, the camera module 305 may include an under-display camera (UDC). As another embodiment, a sensor module 304 may be disposed in the inner space of the electronic device 300 to perform the function thereof without being visually exposed through the front plate 302. For example, in this case, the area of the display 301, which faces the sensor module, may not require the perforated opening.

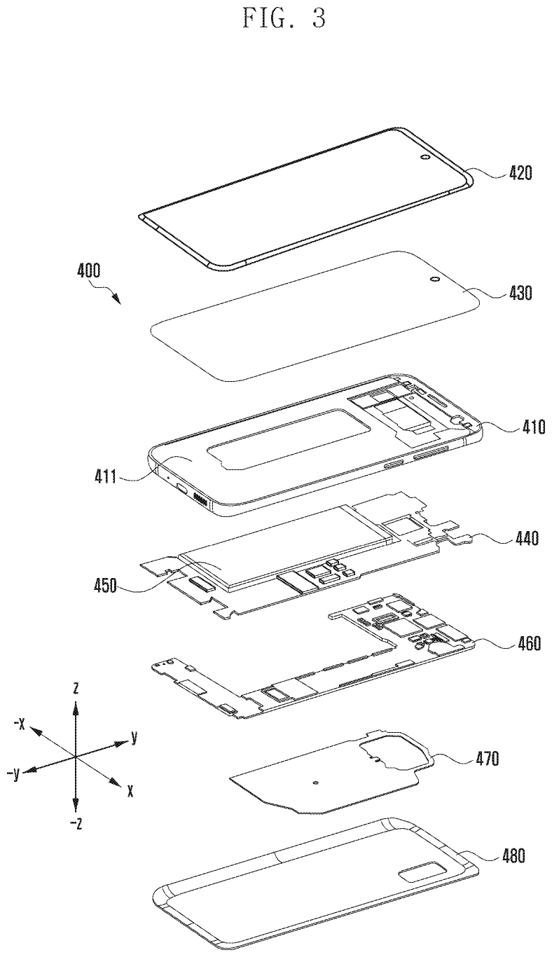

FIG. 3 is a deployed perspective view of an electronic device according to an embodiment of the disclosure.

An electronic device 400 of FIG. 3 according to various embodiments may be at least partially similar to the electronic device 101 of FIG. 1 or the electronic device 300 of FIGS. 2A and 2B, or may include other embodiments of an electronic device.

Referring to FIG. 3, the electronic device 400 may include a side member 410 (e.g., a side bezel structure), a first support member 411 (e.g., a frame, a bracket, or a support structure), a front plate 420 (e.g., a front cover), a display 430, a printed circuit board 440, a battery 450, a second support member 460 (e.g., a frame or a rear case), an antenna 470 (e.g., a flexible printed circuit board (FPCB)), and a rear plate 480 (e.g., a rear cover). In some embodiments, at least one of elements (e.g., the first support member 411 or the second support member 460) may be omitted from the electronic device 400, and other elements may be additionally included therein. At least one of the elements of the electronic device 400 may be the same as or similar to at least one of the elements of the electronic device 300 of FIGS. 2A and 2B, and duplicate descriptions will be omitted below.

The first support member 411 may be disposed inside the electronic device 400, and may be connected to the side member 410 or be integrally formed with the side member 410. For example, the first support member 411 may be formed of a metal material and/or a non-metal (e.g., polymer) material. The first support member 411 may have one surface to which the display 430 is coupled and the other surface to which the printed circuit board 440 is coupled. The printed circuit board 440 may have a processor (e.g., the processor 120 of FIG. 1), memory (e.g., the memory 130 of FIG. 1), and/or an interface (e.g., the interface 177 of FIG. 1) mounted thereon.

For example, the processor may include one or more of a central processing unit (CPU), an application processor (AP), a graphics processing unit (GPU), an image signal processor (ISP), a sensor hub processor, or a communication processor.

For example, the memory may include volatile memory (e.g., the volatile memory 132 of FIG. 1) or non-volatile memory (e.g., the non-volatile memory 134 of FIG. 1).

For example, the interface may include a high-definition multimedia interface (HDMI), a universal serial bus (USB) interface, an SD card interface, and/or an audio interface. For example, the interface may electrically or physically connect the electronic device 400 to an external electronic device, and may include a USB connector, an SD card/multimedia card (MMC) connector, or an audio connector.

The battery 450 (e.g., the battery 189 of FIG. 1) may be a device for supplying power to at least one element of the electronic device 400, and for example, may include a non-rechargeable primary battery, a rechargeable secondary battery, or a fuel cell. For example, at least a portion of the battery 450 may be disposed on substantially the same plane as the printed circuit board 440. The battery 450 may be integrally disposed inside the electronic device 400. As another embodiment, the battery 450 may be disposed detachably from the electronic device 400.

The antenna 470 may be positioned (e.g., attached to the rear plate 480) between the rear plate 480 and the second support member 460. The antenna 470 may include a magnetic secure transmission (MST) antenna, a near field communication (NFC) antenna, and/or a wireless charging antenna. For example, the antenna 470 may perform near-field communication with an external electronic device, or wirelessly transmit and receive power required for charging. In another embodiment, an antenna structure may be formed by a portion of the side bezel structure (i.e., side member 410) and/or the first support member 411, or a combination thereof.

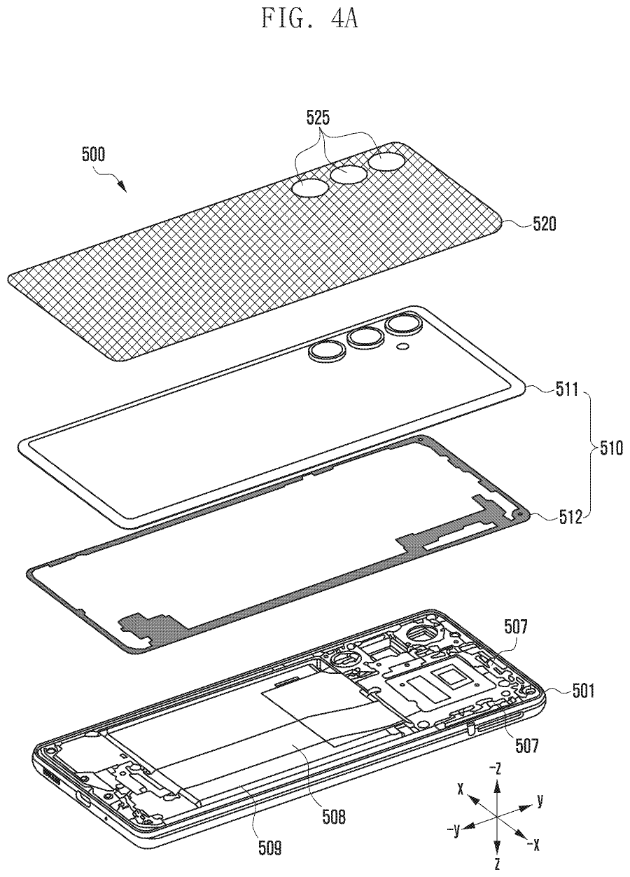

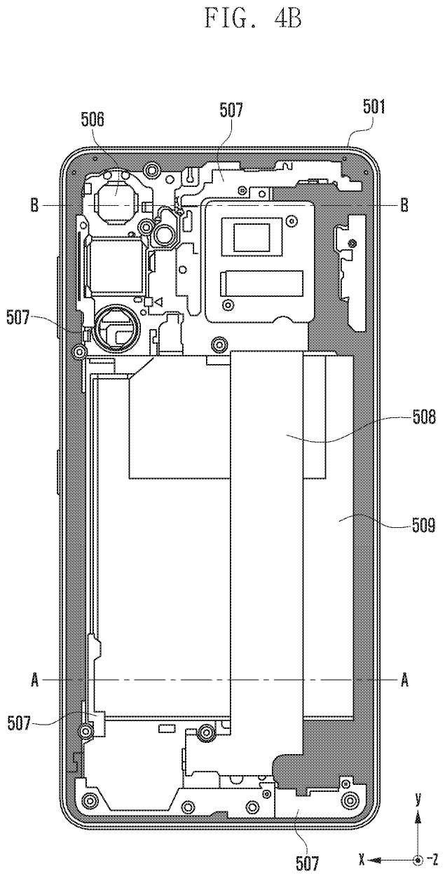

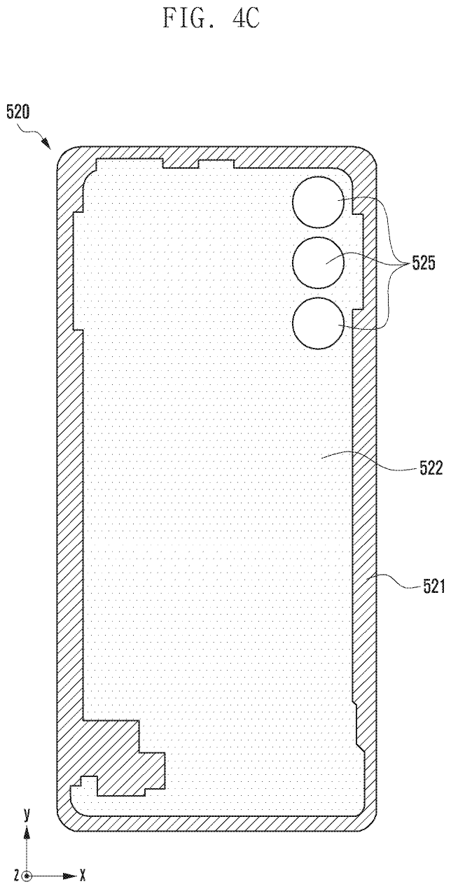

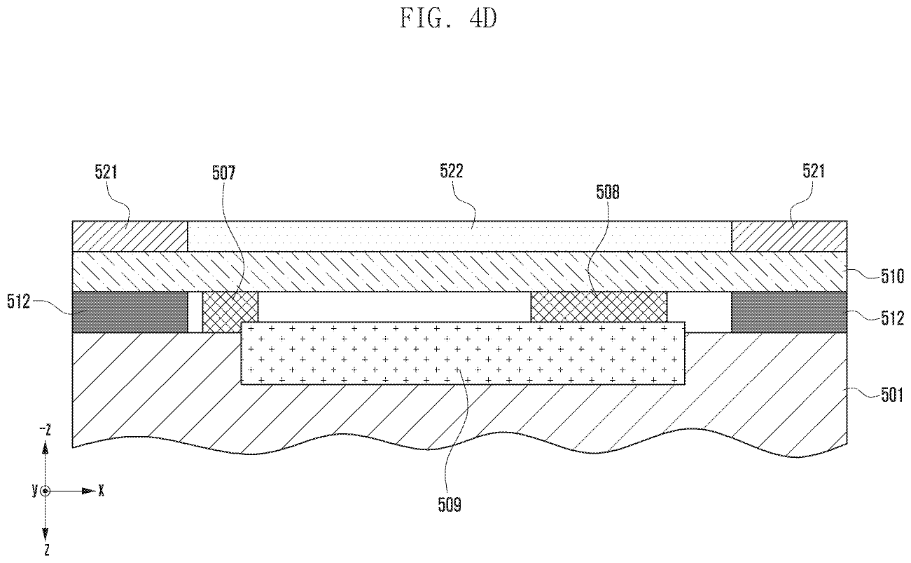

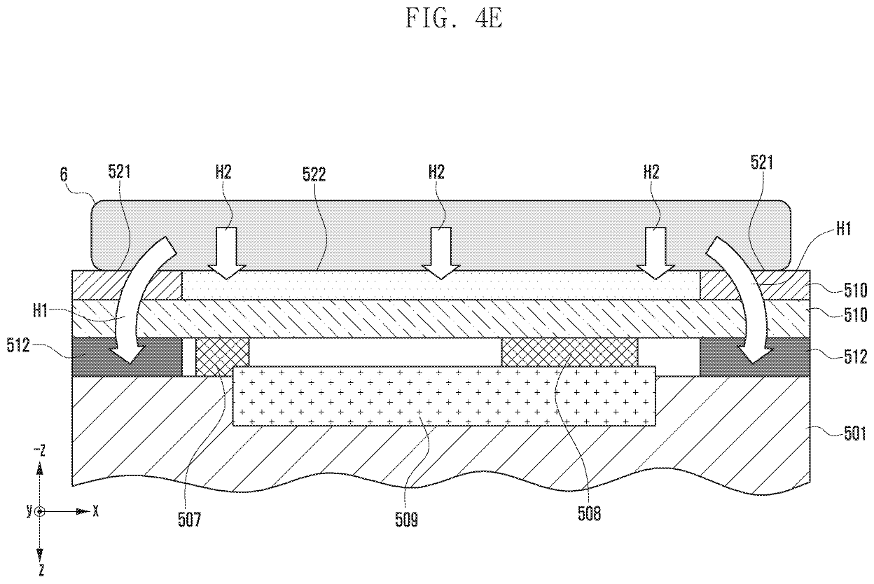

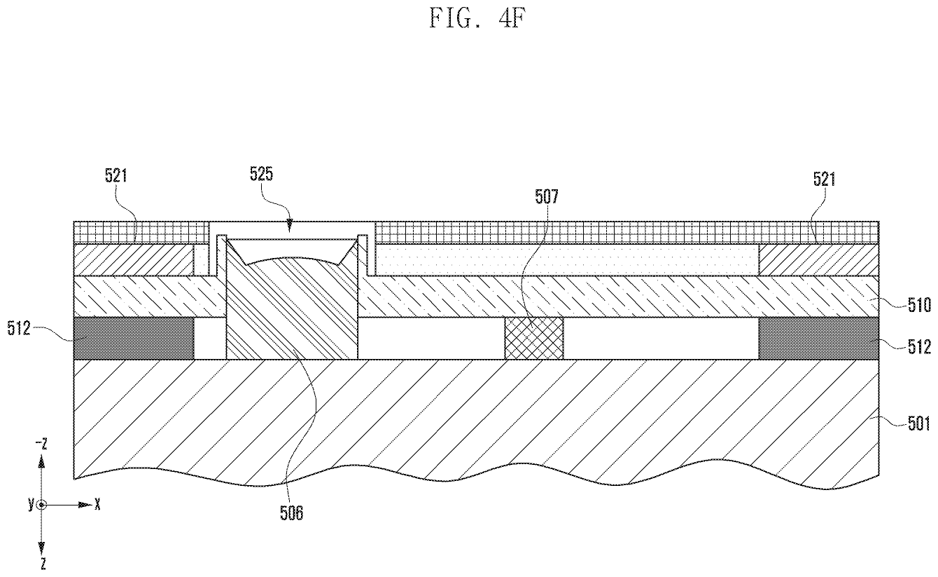

FIG. 4A is an exploded perspective view of an electronic device according to an embodiment of the disclosure.

FIG. 4B is a plan view showing an inner configuration of an electronic device according to an embodiment of the disclosure.

FIG. 4C is a plan view showing a cover plate separation member according to an embodiment of the disclosure.

FIG. 4D is a cross-sectional schematic view showing a cover plate separation member according to an embodiment of the disclosure.

FIG. 4E is a cross-sectional schematic view showing an operation of a cover plate separation member according to an embodiment of the disclosure.

FIG. 4F is a cross-sectional schematic view showing a cover plate separation member according to an embodiment of the disclosure.

The cross sections of FIGS. 4D and 4E are cross-sections taken along the direction A-A of FIG. 4B, and the cross-section of FIG. 4F is a cross-section taken along the direction B-B of FIG. 4B.

Referring to FIGS. 4A and 4B, an electronic device 500 (e.g., the electronic device 101 of FIG. 1, the electronic device 300 of FIGS. 2A and 2B, or the electronic device 400 of FIG. 3) may include a frame 501 (e.g., the first support member 411 and the second support member 460 of FIG. 3), a cover plate 510 (e.g., the front plate 302 and the rear plate 311 of FIGS. 2A and 2B, or the front plate 420 and the rear plate 480 of FIG. 3), a cover plate separation member 520, and elements (e.g., an antenna 507, a cable 508, and/or a battery 509) which are at least partially positioned between the frame 501 and the cover plate 510.

For example, the cover plate 510 may include a rear plate (e.g., the rear plate 311 of FIGS. 2A and 2B, or the rear plate 480 of FIG. 3) and/or a front plate (e.g., the front plate 302 of FIGS. 2A and 2B, or the front plate 420 of FIG. 3). The cover plate 510 may be a member coupled to the rear surface and/or the front surface of the frame 501 so as to protect the inside of the electronic device 500.

The cover plate separation member 520 may be a member configured to be attached in the first direction (e.g., the outside direction of the electronic device 500 or the −z-axis direction in the drawing) of the cover plate 510 of the electronic device 500. The cover plate separation member 520 may be a device which assists in separating the cover plate 510 of the electronic device 500, and may be provided as a standalone device or as a device provided together with the electronic device 500 or the cover plate 510 of the electronic device 500. The detailed configuration of the cover plate separation member 520 will be described later.

The adhesive member 512 may be a member disposed in a partial area (e.g., an area including at least a portion of an outer edge part of the cover plate 510) of a surface (e.g., an inner surface), which faces the second direction (e.g., the z-axis direction), of the cover plate 510, so as to bond the frame 501 and the cover plate 510 to each other. In various embodiments, the adhesive member 512 may prevent external foreign substances such as moisture from being introduced between the frame 501 and the cover plate 510, and thus may provide waterproofing ability to the electronic device 500.

Referring to FIGS. 4C and 4D, the cover plate separation member 520 may include a high thermal conductivity area 521 and a low thermal conductivity area 522. The high thermal conductivity area 521 may have a relatively high thermal conductivity than the low thermal conductivity area 522. For example, the high thermal conductivity area 521 may have a first thermal conductivity, the low thermal conductivity area 522 may have a second thermal conductivity, and the first thermal conductivity may be higher than the second thermal conductivity. The high thermal conductivity area 521 may be positioned to at least partially overlap an area in which the adhesive member 512 is positioned when the cover plate separation member 520 is positioned on the cover plate 510. The low thermal conductivity area 522 may be positioned in an area of the cover plate separation member 520 other than the high thermal conductivity area 521. For example, the high thermal conductivity area 521 may be positioned in at least a portion of the edge area of the cover plate separation member 520, and the low thermal conductivity area may be positioned relatively inward compared to the high thermal conductivity area.

In various embodiments, the high thermal conductivity area 521 may include a material having a high thermal conductivity. For example, the material of the high thermal conductivity area 521 may include a metal foil (e.g., a copper foil, a silver foil, and/or an aluminum foil), graphene, a graphite sheet, and/or a thermal pad (e.g., silicone having heat conductive particles dispersed therein).

In various embodiments, the low thermal conductivity area 522 may include a material having a low thermal conductivity. For example, the material of the low thermal conductivity area 522 may include a polymer film (e.g., polypropylene, polyimide, and/or a polyethylene terephthalate (PET) film) or a porous material (e.g., polystyrene foam, polyethylene foam, ethylene-vinyl acetate (EVA) foam, and/or aerogel) including an air cell. In some embodiments, the low thermal conductivity area 522 may include an air layer 5220.

Referring to FIG. 4E, when the cover plate 510 of the electronic device 500 is separated for repair of the electronic device 500, the electronic device 500 may be heated by a heat source 6 (e.g., an active heat generation body such as a heater, an aqueous solution of sodium acetate, or iron oxide, and/or a thermal storage body such as water or sand) in order to reduce the rigidity and the adhesive forth of the adhesive member 512. In various embodiments, when a cover plate separation member 520 is disposed on the cover plate 510 and a heat source 6 is disposed on the cover plate separation member 520, the high thermal conductivity area 521 may easily transfer heat H1 of the heat source 6 and thus may heat the adhesive member 512, and the low thermal conductivity area 522 may effectively block heat H2 transferred from the heat source 6. Elements of the electronic device 500, such as a battery 509, may experience performance degradation or may be damaged and may cause a fire due to heat transferred from the heat source 6. Therefore, the cover plate separation member 520 of the disclosure may reduce the risk of damage and/or performance degradation of the electronic device 500 and may effectively separate the cover plate 510, by reducing heat transferred to an element such as a battery 509 and increasing heat transferred to the adhesive member 512 by the low thermal conductivity area 522.

Referring to FIGS. 4B and 4F, the electronic device 500 may include a protruding portion (e.g., the camera module 506) which protrudes from the cover plate 510 (e.g., in the −z-axis direction with respect to the cover plate 510). The cover plate separation member 520 may include a cut-out portion (or cut-outs or cut-out portions) 525 formed at a position corresponding to the protruding portion when the cover plate separation member 520 is positioned on the cover plate 510 of the electronic device 500. The cover plate separation member 520 may include the cut-out portion 525, and thus be effectively attached to the cover plate 510 even though the protruding portion of the electronic device 500 protrudes. In addition, the cut-out portion 525 may have a position and a shape corresponding to the protruding portion, and thus the cover plate separation member 520 may be guided to be positioned at an appropriate position on the cover plate 510 when the cover plate 510 is separated.

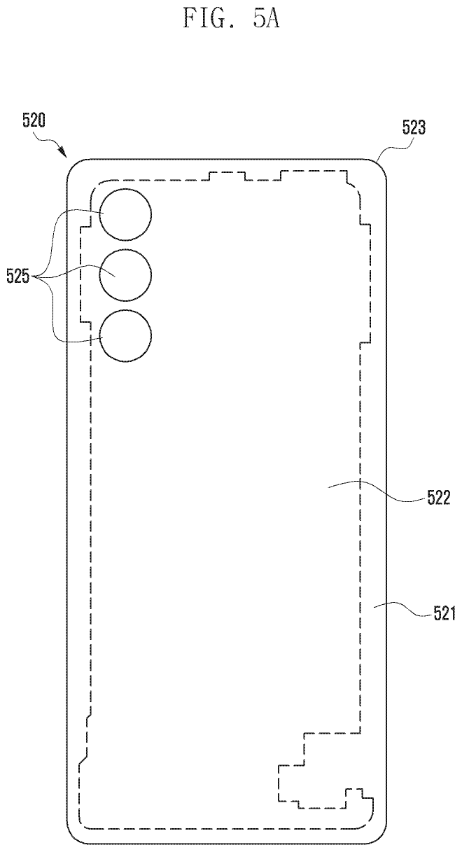

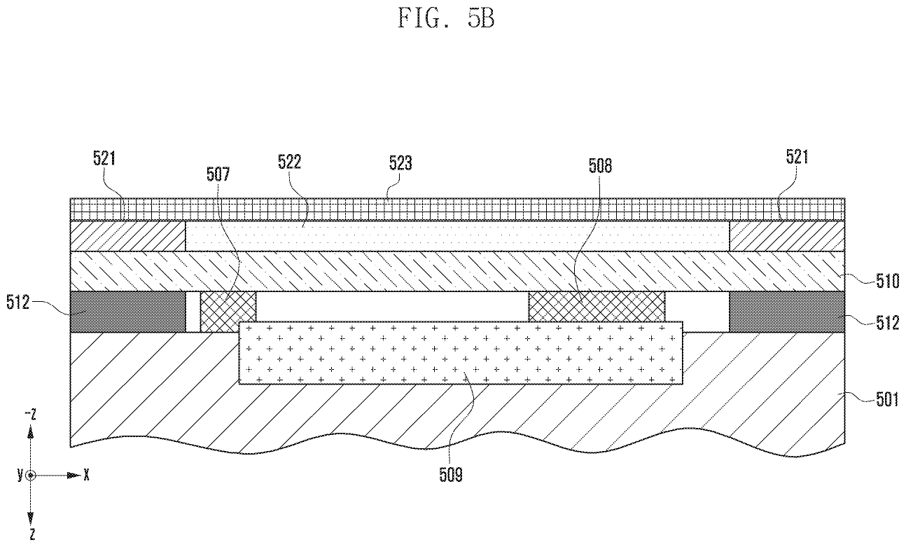

FIG. 5A is a plan view of a cover plate separation member according to an embodiment of the disclosure.

FIG. 5B is a cross-sectional view schematically showing an electronic device according to an embodiment of the disclosure.

Referring to FIGS. 5A and 5B, the electronic device 500 according to various embodiments may include a protective cover 523. The protective cover 523 may be a member which reduces the risk of hazardous elements, such as fragments generated due to breakage of the cover plate 510, scattered toward a worker (a user and a repair personnel of the electronic device 500) who performs the work of separating the cover plate 510 when the cover plate 510 of the electronic device 500 is separated. In various embodiments, the protective cover 523 may also act as a base layer attached to the high thermal conductivity area 521 and the low thermal conductivity area 522. In various embodiments, the low thermal conductivity area 522 may include the air layer 5220, and the base layer may be a member which closes at least a portion of the low thermal conductivity area 522 so as to form the air layer 5220.

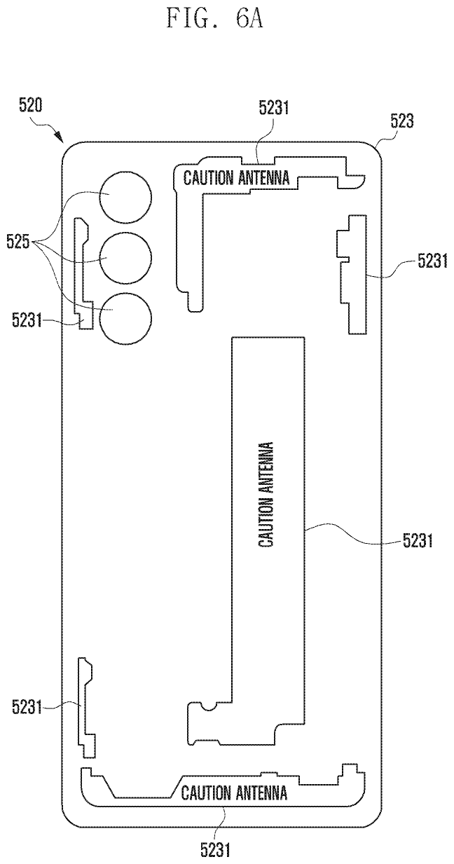

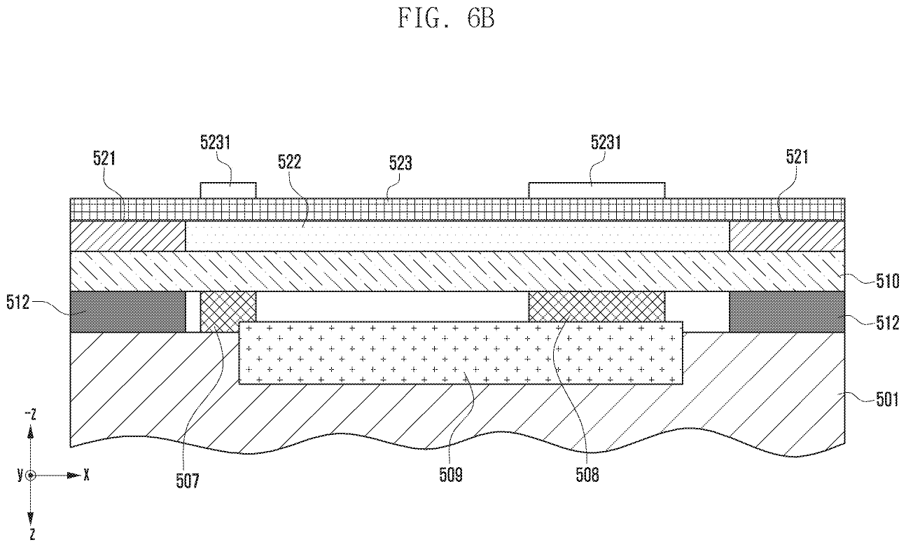

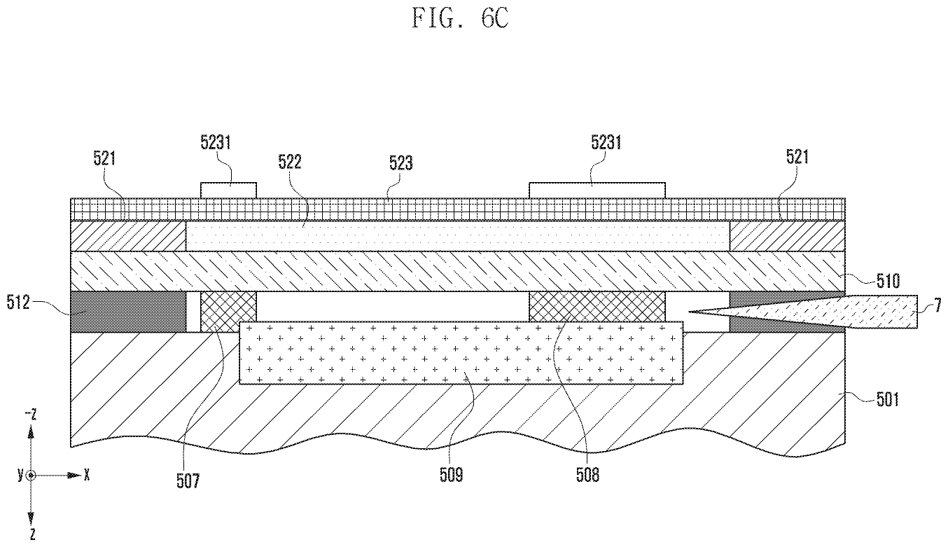

FIG. 6A is a plan view of a cover plate separation member according to an embodiment of the disclosure.

FIG. 6B is a cross-sectional view schematically showing an electronic device according to an embodiment of the disclosure.

FIG. 6C is a schematic view showing a separation operation of a cover plate of an electronic device according to an embodiment of the disclosure.

Referring to FIGS. 6A and 6B, the electronic device 500 according to various embodiments may include a caution display area 5231 formed on a surface (e.g., the surface facing in the −z-axis direction). For example, the caution display area 5231 may be formed on a surface, which faces the first direction (e.g., the −z-axis direction), of the protective cover 523. The caution display area 5231 may be embossed or engraved on the surface of the protective cover 523 and/or printed on the surface of the protective cover 523.

In various embodiments, when the cover plate separation member 520 is positioned on the cover plate 510, the caution display area 5231 may be positioned to at least partially overlap an inner element (e.g., the cable 508 and/or the antenna 507) of the electronic device 500 when viewed in the first direction (e.g., the −z-axis direction). In various embodiments, the caution display area 5231 may include a warning message (e.g., “CAUTION CABLE” or “CAUTION ANTENNA”) and/or a warning symbol.

Referring to FIG. 6C, when separating the cover plate 510 of the electronic device 500, a worker (e.g., a user or a repair personnel of the electronic device 500) may use a wedge 7 (e.g., a tool such as a pick). The wedge 7 may be inserted between the frame 501 and the cover plate 510 to cut the adhesive member 512 and/or lift the cover plate 510 so as to separate the cover plate 510 from the frame 501. When the wedge 7 is inserted too deeply into the inside of the electronic device 500 during the above-described operation, the inner element (e.g., the cable 508 and/or the antenna 507 positioned between the cover plate 510 and the frame 501) of the electronic device 500 may be damaged by the wedge 7. The cover plate separation member 520 of the disclosure can effectively warn a worker for the position of the inner element of the electronic device 500 through the caution display area 5231, and thus reduce the risk in which the inner element is damaged by the worker.

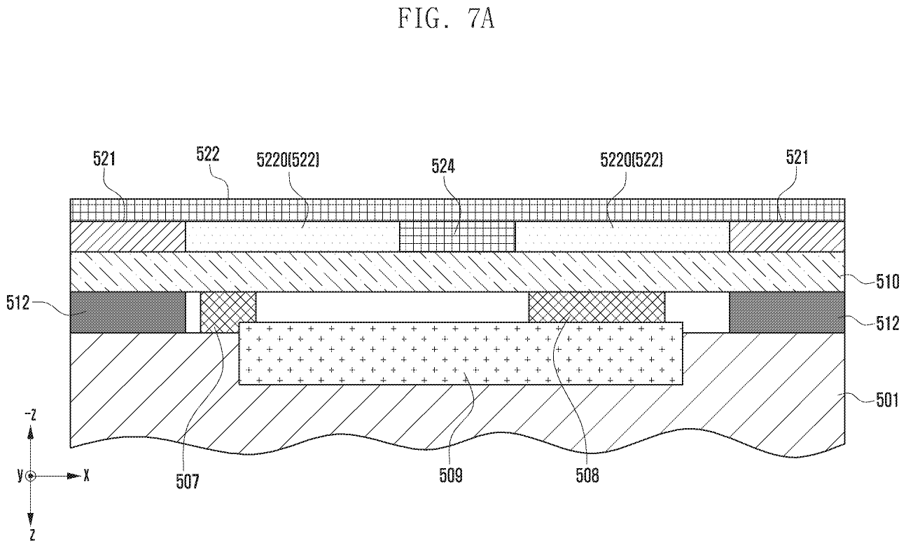

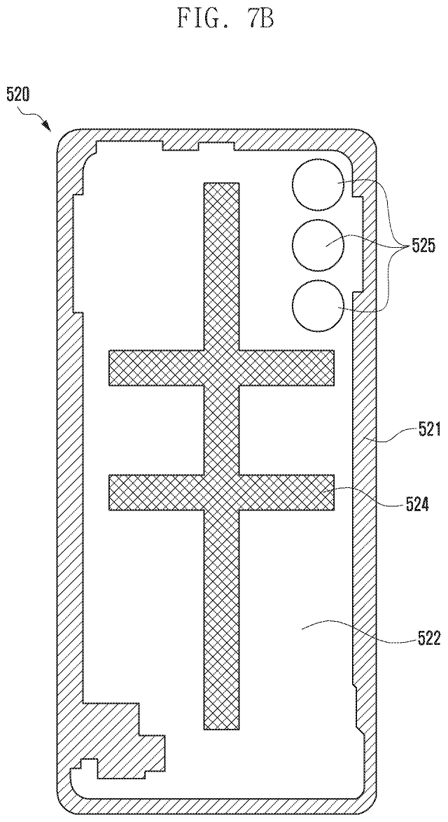

FIG. 7A is a cross-sectional view schematically showing an electronic device according to an embodiment of the disclosure.

FIG. 7B is a plan view of a cover plate separation member according to an embodiment of the disclosure.

Referring to FIGS. 7A and 7B, the cover plate separation member 520 may include a protective cover 523, an air layer 5220, and a support member 524. In relation to the protective cover 523, the description with reference to FIGS. 5A and 5B may be referred to as long as not contradictory. The air layer 5220 may be an at least partially closed area which is formed in an area corresponding to the low thermal conductivity area 522 between the protective cover 523 and the cover plate 510 and contains air. The support member 524 may be a member supporting the protective cover 523 so that the state, in which the protective cover 523 is spaced apart from the cover plate 510, is maintained.

For example, the support member 524 may have various shapes such as a linear shape, a diagonal shape, a cross shape, and/or a shape having one or more branches, which allow the protective cover 523 and the cover plate 510 to be spaced apart from each other and thus the air layer 5220 to be maintained.

Since air has a low thermal conductivity, the low thermal conductivity area 522 may include the air layer 5220. When the protective cover 523 forming the air layer 5220 is flexible, the protective cover 523 may collapse onto the surface of the cover plate 510 so that the air layer 5220 cannot be maintained. Accordingly, the support member 524 may support and assist the protective cover 523 so that the air layer 5220 is maintained and the low thermal conductivity area 522 maintains the low thermal conductivity. The support member 524 may include a material (e.g., a polymer or polymer foam) having a low thermal conductivity and the like.

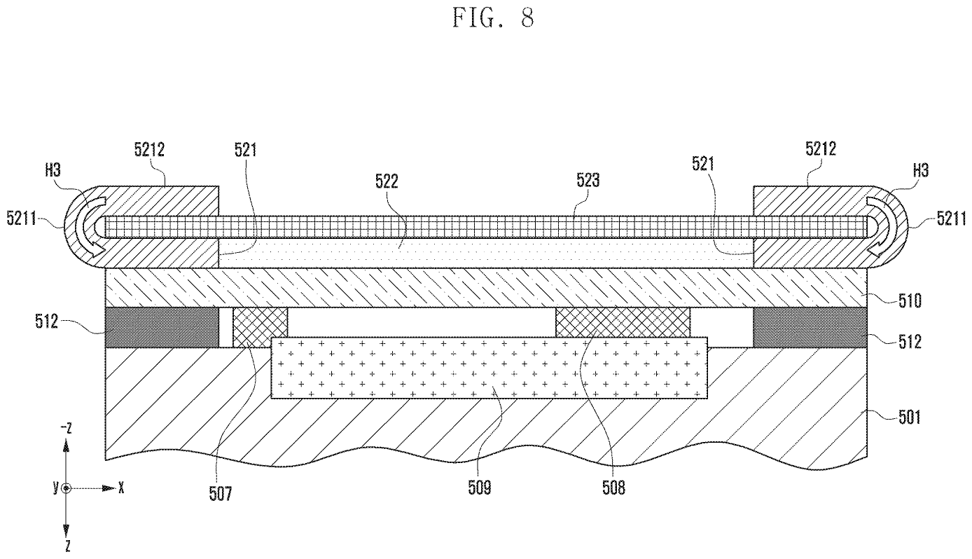

FIG. 8 is a cross-sectional view showing an electronic device according to an embodiment of the disclosure.

Referring to FIG. 8, the high thermal conductivity area 521 of the electronic device 500 according to various embodiments may extend to an upper surface (e.g., the surface facing the −z-axis direction) of the protective cover 523. For example, the high thermal conductivity area 521 may be bent from a side surface of the protective cover 523 to form a bent portion 5211, and may extend to an edge area of the upper surface of the protective cover 523 to form an extension portion 5212.

When heat is applied in order to separate the cover plate 510 of the electronic device 500, the high thermal conductivity area 521 extending to the upper surface of the protective cover 523 may form an additional heat transfer path H3 through which heat of the heat source 6 (e.g., the heat source 6 of FIG. 4E) is transferred to the adhesive member 512. Accordingly, the adhesive forth of the adhesive member 512 may be effectively reduced so that the cover plate 510 is easily separated. In addition, since the time required for separating the cover plate 510 is shortened, the thermal load applied to an element such as the battery 509 may be reduced.

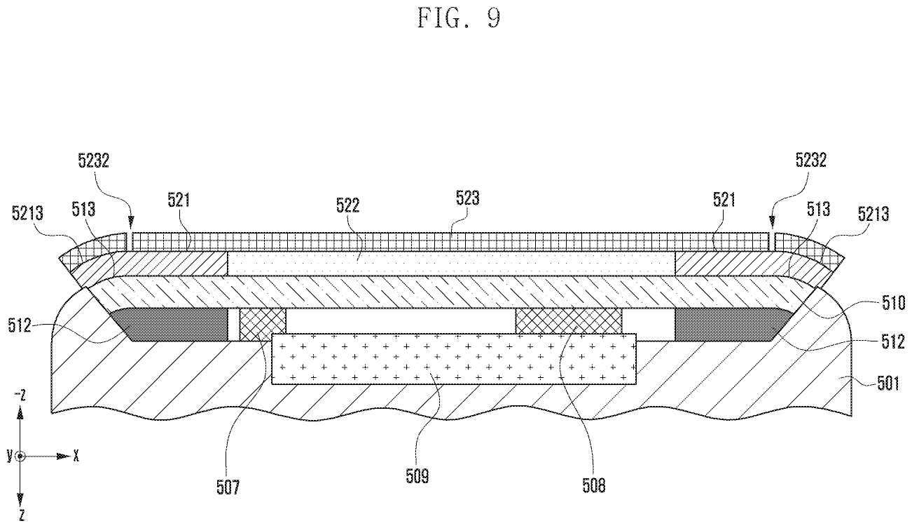

FIG. 9 is a cross-sectional view showing an electronic device 500 according to an embodiment of the disclosure.

Referring to FIG. 9, the electronic device 500 may include a curved-surface portion 513 formed at an edge portion. For example, the curved-surface portion 513 may be formed at an edge portion of the cover plate 510. The curved-surface portion 513 may be a portion which enhances the appearance and ergonomics of the electronic device 500.

In various embodiments, when the cover plate separation member 520 is positioned on the cover plate 510, a portion, which is corresponds to the curved-surface portion 513, of the high thermal conductivity area 521 of the cover plate separation member 520 may be bent. A bent portion 5213 may be formed to have a curvature corresponding to the curvature of the curved-surface portion 513. For example, the high thermal conductivity area 521 may include a metal foil, and an edge portion of the metal foil may be plastically deformed to have a curvature corresponding to the curved-surface portion 513 when the cover plate separation member 520 is attached to the cover plate 510. As the high thermal conductivity area 521 is bent, the cover plate separation member 520 may be effectively in close contact with the electronic device 500 having the curved-surface portion 513. In various embodiments, the protective cover 523 may include a segment 5232 formed at a portion corresponding to a boundary between the bent portion 5213 and a flat portion of the high thermal conductivity area 521. Since the protective cover 523 includes the segment 5232, the metal foil can be effectively bent.

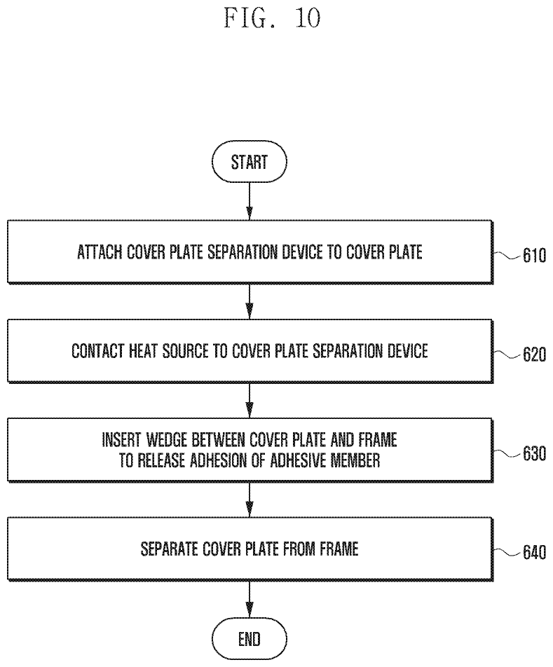

FIG. 10 is a flowchart showing a method for separating an cover plate of an electronic device 500 according to an embodiment of the disclosure.

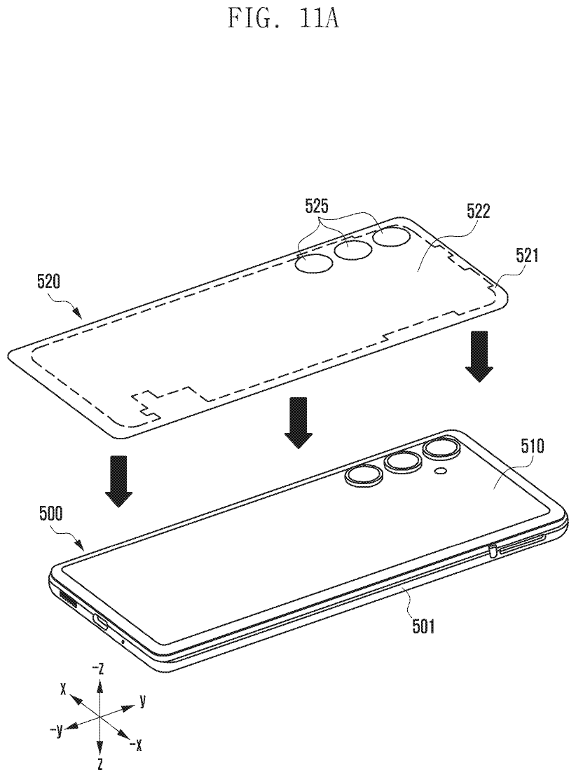

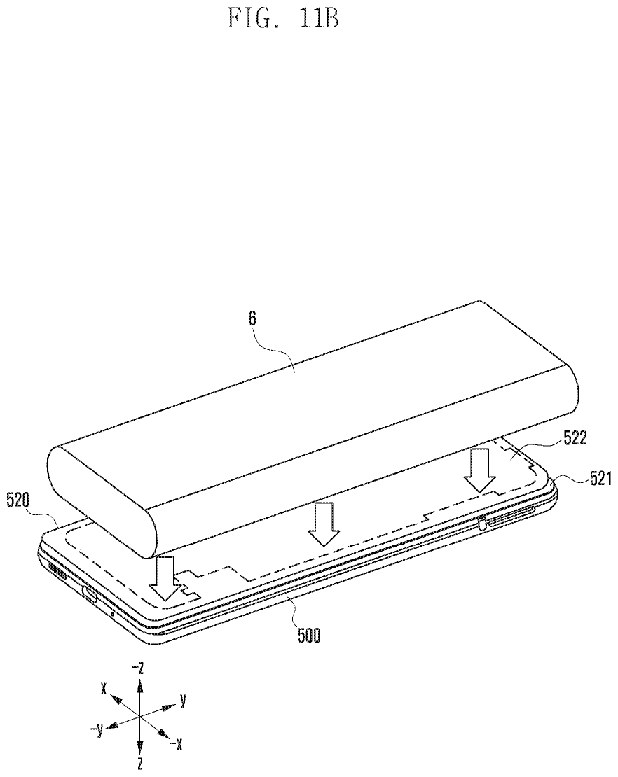

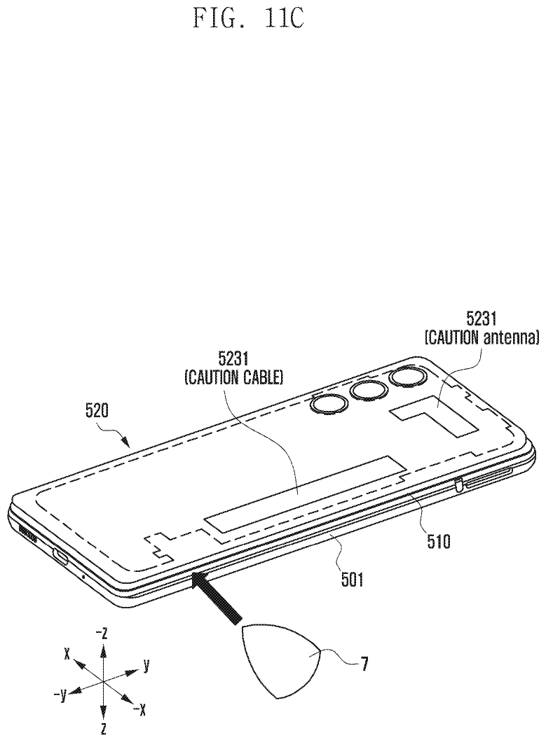

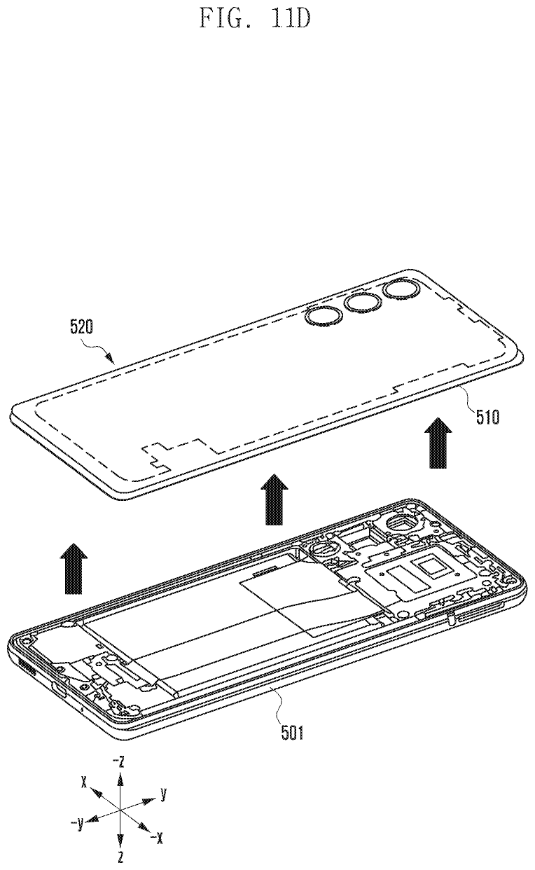

FIGS. 11A to 11D are schematic diagrams showing operations of removing a cover plate of an electronic device according to various embodiments of the disclosure. Referring to FIG. 10, a method for separating the cover plate 510 of the electronic device 500 may include an attachment operation, a heating operation, an adhesion release operation, and a separation operation.

Referring to FIGS. 10 and 11A, the attachment operation may include an operation of attaching the cover plate separation member 520 to the cover plate 510 of the electronic device 500 in the first direction (e.g., the −z-axis direction). The cover plate separation member 520 may include a high thermal conductivity area 521 and may be attached to at least partially overlap the adhesive member 512 of the electronic device 500 when the cover plate separation member 520 is attached to the cover plate 510 in the attachment operation. In various embodiments, the cover plate separation member 520 may include a cut-out portion 525 having a position and a shape corresponding to a protruding portion (e.g., the camera module 506) of the electronic device 500. In the attachment operation, the cut-out portion 525 may assist such that the high thermal conductivity area 521 of the cover plate separation member 520 and the adhesive member 512 of the electronic device 500 are aligned with each other.

Referring to FIGS. 10 and 11B, the heating operation may include an operation of contacting a heat source to the cover plate separation member 520 in the first direction (e.g., the −z-axis direction) and heating the adhesive member 512 to reduce the adhesive forth of the adhesive member 512. For example, the heat source of the electronic device 500 may include an active heat generation body such as a heater, an aqueous solution of sodium acetate, or iron oxide, and/or a thermal storage body such as water or sand. In various embodiments, the cover plate separation member 520 may include a low thermal conductivity area 522 positioned to at least partially overlap an area, in which the adhesive member 512 is not positioned, of the electronic device 500. The low thermal conductivity area 522 may prevent or reduce an area, in which the adhesive member 512 is not disposed, of the electronic device 500 from being excessively heated by the heat source 6.

Referring to FIGS. 10 and 11C, the adhesion release operation may include an operation of inserting a wedge 7 (e.g., a tool such as a pick) between the frame 501 and the cover plate 510 of the electronic device 500 to release adhesion of the adhesive member 512 of which the adhesive forth has been reduced by the heating operation.

In various embodiments, the cover plate separation member 520 may include a caution display area 5231. As illustrated in FIGS. 6A and 6B, the caution display area 5231 may be positioned to at least partially overlap an inner element (e.g., the cable 508 and/or the antenna 507) of the electronic device 500 when viewed in the first direction (e.g., the −z-axis direction). Since the caution display area 5231 is positioned to overlap the inner element, a worker (e.g., a user or a repair personnel of the electronic device 500) may refer to the caution display area when inserting the wedge 7 between the frame 501 and the cover plate 510 of the electronic device 500 so that the risk, in which the inner element of the electronic device 500 is damaged, is reduced.

Referring to FIGS. 10 and 11D, the separation operation may be an operation of lifting and separating the cover plate 510 in a state where the adhesive of the adhesive member 512 bonding between the cover plate 510 and the frame 501 is at least partially released.

A cover plate separation member 520 according to various embodiments of the disclosure may be a cover plate separation member 520 for an electronic device 500 including a frame 501, a cover plate 510, and an adhesive member 512 configured to bond the frame 501 and the cover plate 510, and may include a high thermal conductivity area 521 having a relatively high thermal conductivity and positioned to at least partially overlap the adhesive member 512 when the cover plate separation member 520 is positioned on the cover plate 510, and a low thermal conductivity area 522 having a relatively low thermal conductivity compared to the high thermal conductivity area 521 and positioned to at least partially overlap an area of the electronic device 500, in which the adhesive member 512 is not positioned when the cover plate separation member 520 is positioned on the cover plate 510.

In various embodiments, the cover plate separation member 520 may include a protective cover 523 positioned in a first direction opposite to a direction facing the cover plate 510 when the cover plate separation member 520 is positioned on the cover plate 510.

In various embodiments, the electronic device 500 may include at least one inner element positioned between the frame 501 and the cover plate 510, and the protective cover 523 may include a caution display area 5231 formed on a surface facing the first direction and positioned to overlap the at least one inner element.

In various embodiments, the low thermal conductivity area 522 may include an air layer 5220 formed between the cover plate 510 and the protective cover 523 when the cover plate separation member 520 is positioned on the cover plate 510.

In various embodiments, the cover plate separation member 520 may include a support member 524 which is positioned between the cover plate 510 and the protective cover 523 when the cover plate separation member 520 is positioned on the cover plate 510 and supports the protective cover 523 so that the protective cover 523 and the cover plate 510 are spaced apart from each other.

In various embodiments, the high thermal conductivity area 521 may extend to cover a side surface of the protective cover 523 and at least a portion of a surface, which faces the first direction, of the protective cover 523.

In various embodiments, the high thermal conductivity area 521 may include a metal foil.

In various embodiments, the electronic device 500 may include a curved-surface portion 513 formed in at least a portion of an edge of the cover plate 510, and the metal foil may have a portion which corresponds to the curved-surface portion 513 and is bent to correspond to a curvature of the curved-surface portion 513 when the cover plate separation member 520 is positioned on the cover plate 510.

In various embodiments, the electronic device 500 may include at least one protruding portion formed on the cover plate 510, and

the cover plate separation member 520 may include a cut-out portion 525 which has a position and a shape corresponding to the protruding portion and is formed such that at least a portion of the protruding portion is positioned therein when positioned on the cover plate 510.

A cover plate 510 according to various embodiments of the disclosure may include a cover plate body 511, a cover plate separation member 520 configured to be attachable to a surface, which faces a first direction, of the cover plate 510, and an adhesive member 512 positioned on at least a portion of an outer edge portion of a surface, which faces a second direction opposite to the first direction, of the cover plate 510. The cover plate separation member 520 may include a high thermal conductivity area 521 having a relatively high thermal conductivity and positioned to at least partially overlap the adhesive member 512 when the cover plate separation member 520 is positioned on the cover plate 510, and a low thermal conductivity area 522 having a relatively low thermal conductivity compared to the high thermal conductivity area 521 and positioned to at least partially overlap an area of the electronic device 500, in which the adhesive member 512 is not positioned when the cover plate separation member 520 is positioned on the cover plate 510.

In various embodiments, the cover plate separation member 520 may include a protective cover 523 positioned in a first direction opposite to a direction facing the cover plate 510 when positioned on the cover plate 510.

In various embodiments, the low thermal conductivity area 522 may include an air layer 5220 formed between the cover plate 510 and the protective cover 523 when the cover plate separation member 520 is positioned on the cover plate 510.

In various embodiments, the high thermal conductivity area 521 may extend to cover a side surface of the protective cover 523 and at least a portion of a surface, which faces the first direction, of the protective cover 523.

In various embodiments, the high thermal conductivity area 521 may include a metal foil.

In various embodiments, the cover plate 510 may include a curved-surface portion 513 formed in at least a portion of an edge thereof, and the metal foil may have a portion which corresponds to the curved-surface portion 513 and is bent to correspond to a curvature of the curved-surface portion 513 when the cover plate separation member 520 is positioned on the cover plate 510.

An electronic device 500 according to various embodiments of the disclosure may include a frame 501, a cover plate 510 positioned in a first direction with respect to the frame 501, an adhesive member 512 positioned in at least a partial area between the frame 501 and the cover plate 510 and configured to bond the frame 501 and the cover plate 510, and a cover plate separation member 520 configured to be attachable in the first direction with respect to the cover plate 510. The cover plate separation member 520 may include a high thermal conductivity area 521 having a relatively high thermal conductivity and positioned to at least partially overlap the adhesive member 512 when the cover plate separation member 520 is positioned on the cover plate 510, and a low thermal conductivity area 522 having a relatively low thermal conductivity compared to the high thermal conductivity area 521 and positioned to at least partially overlap an area of the electronic device 500, in which the adhesive member 512 is not positioned when the cover plate separation member 520 is positioned on the cover plate 510.

In various embodiments, the cover plate separation member 520 may include a protective cover 523 positioned in a first direction opposite to a direction facing the cover plate 510 when positioned on the cover plate 510.

In various embodiments, the electronic device 500 may include at least one inner element positioned between the frame 501 and the cover plate 510, and the protective cover 523 may include a caution display area 5231 formed on a surface facing the first direction and positioned to overlap the at least one inner element.

In various embodiments, the high thermal conductivity area 521 may include a metal foil.

In various embodiments, the electronic device 500 may include at least one protruding portion formed on the cover plate 510, and the cover plate separation member 520 may include a cut-out portion 525 which has a position and a shape corresponding to the protruding portion and is formed such that at least a portion of the protruding portion is positioned therein when positioned on the cover plate 510.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A cover plate separation member for an electronic device comprising a frame, a cover plate, and an adhesive member configured to bond the frame and the cover plate, the cover plate separation member comprising:
a high thermal conductivity area which has a first thermal conductivity and is positioned to at least partially overlap the adhesive member when the cover plate separation member is positioned on the cover plate; and
a low thermal conductivity area which has a second thermal conductivity relatively low compared to the first thermal conductivity and is positioned to at least partially overlap an area of the electronic device, in which the adhesive member is not positioned when the cover plate separation member is positioned on the cover plate.

2. The cover plate separation member of claim 1, further comprising a protective cover positioned in a first direction opposite to a direction facing the cover plate when the cover plate separation member is positioned on the cover plate.

3. The cover plate separation member of claim 2,
wherein the electronic device comprises at least one inner element positioned between the frame and the cover plate, and
wherein the protective cover comprises a caution display area formed on a surface facing the first direction and positioned to overlap the at least one inner element.

4. The cover plate separation member of claim 2, wherein the low thermal conductivity area comprises an air layer formed between the cover plate and the protective cover when the cover plate separation member is positioned on the cover plate.

5. The cover plate separation member of claim 4, further comprising a support member which is positioned between the cover plate and the protective cover when the cover plate separation member is positioned on the cover plate and supports the protective cover so that the protective cover and the cover plate are spaced apart from each other.

6. The cover plate separation member of claim 2, wherein the high thermal conductivity area extends to cover a side surface of the protective cover and at least a portion of a surface, which faces the first direction, of the protective cover.

7. The cover plate separation member of claim 1, wherein the high thermal conductivity area comprises a metal foil.

8. The cover plate separation member of claim 7,
wherein the electronic device comprises a curved-surface portion formed in at least a portion of an edge of the cover plate, and
wherein the metal foil has a portion which corresponds to the curved-surface portion and is bent to correspond to a curvature of the curved-surface portion when the cover plate separation member is positioned on the cover plate.

9. The cover plate separation member of claim 1,
wherein the electronic device comprises at least one protruding portion formed on the cover plate, and
wherein the cover plate separation member comprises a cut-out portion which has a position and a shape corresponding to the protruding portion and is formed such that at least a portion of the protruding portion is positioned therein when positioned on the cover plate.

10. An electronic device comprising:
a frame;
a cover plate positioned in a first direction with respect to the frame;
an adhesive member positioned in at least a partial area between the frame and the cover plate and configured to bond the frame and the cover plate; and
a cover plate separation member configured to be attachable in the first direction with respect to the cover plate,
wherein the cover plate separation member comprises:
a high thermal conductivity area which has a relatively high thermal conductivity and is positioned to at least partially overlap the adhesive member when the cover plate separation member is positioned on the cover plate, and
a low thermal conductivity area which has a relatively low thermal conductivity compared to the high thermal conductivity area and is positioned to at least partially overlap an area of the electronic device, in which the adhesive member is not positioned when the cover plate separation member is positioned on the cover plate.

11. The electronic device of claim 10, further comprising a protective cover positioned in a first direction opposite to a direction facing the cover plate when the cover plate separation member is positioned on the cover plate.

12. The electronic device of claim 11, further comprising:
at least one inner element positioned between the frame and the cover plate,
wherein the protective cover comprises a caution display area formed on a surface facing the first direction and positioned to overlap the at least one inner element.

13. The electronic device of claim 11, wherein the low thermal conductivity area comprises an air layer formed between the cover plate and the protective cover when the cover plate separation member is positioned on the cover plate.

14. The electronic device of claim 13, further comprising a support member which is positioned between the cover plate and the protective cover when the cover plate separation member is positioned on the cover plate and supports the protective cover so that the protective cover and the cover plate are spaced apart from each other.

15. The electronic device of claim 10, wherein the high thermal conductivity area comprises a metal foil.

16. The electronic device of claim 10, wherein the electronic device comprises at least one protruding portion formed on the cover plate, and
wherein the cover plate separation member comprises a cut-out portion which has a position and a shape corresponding to the protruding portion and is formed such that at least a portion of the protruding portion is positioned therein when positioned on the cover plate.

17. A method for separating a cover plate of an electronic device,
wherein the electronic device comprises:
a frame,
a cover plate positioned in a first direction with respect to the frame, and
an adhesive member positioned in at least a partial area between the frame and the cover plate and configured to bond the frame and the cover plate,
wherein the method for separating a cover plate comprises:
an attachment operation of attaching a cover plate separation member to the cover plate in a first direction,
a heating operation of contacting a heat source to the cover plate separation member in the first direction,
an adhesion release operation of inserting a wedge between the frame and the cover plate to remove adhesion of the adhesive member, and
a separation operation of separating the cover plate from the frame, and
wherein the cover plate separation member comprises:
a high thermal conductivity area which has a relatively high thermal conductivity and is positioned to at least partially overlap the adhesive member when the cover plate separation member is positioned on the cover plate, and
a low thermal conductivity area which has a relatively low thermal conductivity compared to the high thermal conductivity area and is positioned to at least partially overlap an area of the electronic device, in which the adhesive member is not positioned when the cover plate separation member is attached on the cover plate.

18. The method of claim 17,
wherein the electronic device comprises at least one protruding portion protruding from the cover plate,
wherein the cover plate separation member comprises a cut-out portion having a position and a shape corresponding to the protruding portion, and
wherein the attachment operation comprises an operation of aligning the cover plate separation member with respect to the cover plate with reference to the protruding portion and the cut-out portion.

19. The method of claim 17, wherein the cover plate includes a protective cover positioned in a first direction opposite to a direction facing the cover plate when the cover plate separation member is positioned on the cover plate.

20. The method of claim 19,
wherein the electronic device comprises at least one inner element positioned between the frame and the cover plate,
wherein the protective cover comprises a caution display area formed on a surface facing the first direction and positioned to overlap the at least one inner, and
wherein the adhesion release operation comprises an operation of inserting a wedge between the frame and the cover plate while avoiding the caution display area.
